(19) United States
(12) Patent Application Publication
(10) Pub. No.: US 2010/0089851 A1
(43) Pub. Date: Apr. 15, 2010

(54) DEVICES AND METHODS FOR HANDLING MICROELECTRONIC ASSEMBLIES

(75) Inventors: Michael R. Slaughter, Boise, ID (US); Justin L. Lawrence, Meridian, ID (US); John E. Vannortwick, Kuna, ID (US); Jamie J. Wanke, Boise, ID (US); Christopher E. Casey, Meridian, ID (US); Michael R. Forbis, Meridian, ID (US); James R. Stoor, Boise, ID (US)

Correspondence Address: DAY PITNEY LLP;ACCOUNT: ILLINOIS TOOL WORKS INC., 7 TIMES SQUARE, NEW YORK, NY, 10036-7311, US

(73) Assignee: MICRON TECHNOLOGY, INC., Boise, ID (US)

(21) Appl. No.: 12/252,292

(22) Filed: Oct. 15, 2008

(51) Int. Cl. B25H 3/04; B29C 45/00; H01L 21/677

(52) U.S. Cl. 211/126.2; 414/787; 264/478; 414/800

(57) ABSTRACT

Handling devices and methods for handling microelectronic assemblies are disclosed herein. In one embodiment, a frame includes a first end portion, a second end portion that is spaced along a longitudinal axis from the first end portion, a first side portion that couples the first and second end portions, and a second side portion that couples the first and second end portions and is spaced along a lateral axis from the first side portion. An insert is releasably disposed on the frame and includes a plurality of pockets, with individual pockets positioned to releasably receive a respective one of the microelectronic assemblies. A retainer is positioned to secure and release the insert with respect to the frame.

### TECHNICAL FIELD

The present disclosure is generally related to devices and methods for handling microelectronic assemblies. In particular, the present disclosure is related to devices (e.g., trays) and methods for handling packaged microelectronic devices or assemblies, non-packaged microelectronic devices or assemblies, or image sensor devices or assemblies.

### BACKGROUND

Typically, trays can be used to reduce damage to microelectronic assemblies, such as memory devices and microprocessors, and to increase the efficiencies in handling and shipping microelectronic assemblies. The Joint Electron Device Engineering Council (JEDEC) has promulgated design requirements to standardize trays used by the microelectronic assembly manufacturers and customers. For example, JEDEC Publication 95, Design Guide 4.10, “Generic Shipping & Handling Matrix Tray,” standardizes the physical and functional characteristics of the trays, including the length, width, thickness, capacity, stack-ability, and other characteristics of the trays.

Typically, a specific tray is developed for each specific microelectronic assembly, and a new injection mold is required to form each specific tray. The injection molds, however, are typically expensive and time consuming to develop. With injection molds costing up to twenty thousand dollars or more, the start-up cost to create a mold is relatively high, particularly when a small number of engineering samples of a multi-chip package assembly are being processed for evaluation by potential customers. Moreover, because injection molds can take eight to twelve weeks or more to develop, the time required to develop a tray can be the limiting factor in developing a new microelectronic assembly.

### BRIEF DESCRIPTION OF THE DRAWINGS

FIG. 1 is an exploded perspective view of a handling device for microelectronic assemblies in accordance with an embodiment of the disclosure.

FIG. 2 is a cross-sectional view illustrating a secured configuration and a released configuration of an insert panel with respect to a portion of the frame for the handling device shown in FIG. 1.

FIG. 3 shows a perspective view of a handling device for microelectronic assemblies in accordance with another embodiment of the disclosure.

FIG. 4 is a perspective view of a frame for the handling device shown in FIG. 3.

FIG. 5 is a perspective view of a handling device carrying microelectronic assemblies in accordance with yet another embodiment of the disclosure.

FIG. 6 is an enlarged view of a portion of a handling device for microelectronic assemblies in accordance with a further embodiment of the disclosure.

FIG. 7 is an exploded perspective view of a handling device for microelectronic assemblies in accordance with yet a further embodiment of the disclosure.

### DETAILED DESCRIPTION

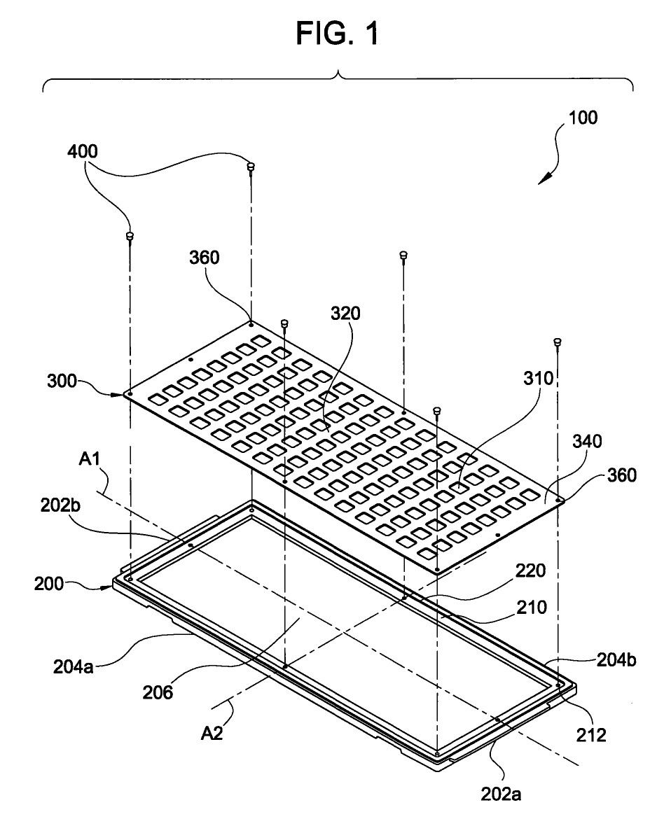

Specific details of several embodiments of the disclosure are described below with reference to microelectronic assembly handling devices and methods for handling microelectronic assemblies. As it is used in the present disclosure, the phrase “microelectronic assemblies” can include packaged microelectronic assemblies or devices, bare dies and other non-packaged microelectronic assemblies or devices, image sensor assemblies and devices, or other semiconductor components. Packaged microelectronic assemblies can include, for example, micromechanical components, data storage elements, optics, read/write components, or other features. Non-packaged microelectronic assemblies can include, for example, microelectronic dies for flash memory (e.g., NAND flash memory), SRAM, DRAM (e.g., DDR-SDRAM), processors, imagers, and other types of devices. The term “handling” can include a manual or automated method or process by which something is moved, carried, transported, delivered, shipped, worked-on, or otherwise manipulated in connection with microelectronic assemblies. The phrase “coupled” can include a physical association or structural linking of two or more components or features. Other embodiments according to the disclosure can have configurations, components, features or procedures different than those described in this section. A person of ordinary skill in the relevant art, therefore, will accordingly understand that the disclosure may have other embodiments with additional elements, or the disclosure may have other embodiments without several of the elements shown and described below with reference to FIGS. 1-7.

FIG. 1 is an exploded perspective view of a handling device 100 for microelectronic assemblies in accordance with an embodiment of the disclosure. The handling device 100 can include a frame 200, an insert (e.g., an insert panel) 300, and one or more retainers 400 that releasably secure the frame 200 and the insert panel 300.

In the embodiment shown in FIG. 1, the frame 200 has a rectangular shape and size in accordance with JEDEC design requirements. According to other embodiments, a frame can have other suitable shapes and/or sizes. The frame 200 includes a first end portion 202a and a second end portion 202b. The second end portion 202b is spaced along a longitudinal axis A1 from the first end portion 202a. The frame 200 also includes a first side portion 204a and a second side portion 204b. The second side portion 204b is spaced along a lateral axis A2 from the first side portion 204a. The first and second end portions 202a and 202b and the first and second side portions 204a and 204b define a platform 210 positioned around an aperture 206 to support the insert panel 300, and the frame 200 also includes a rim 220 that projects from the platform 210 to position the insert panel 300 on the platform 210.

Embodiments of the frame 200 are configured to be formed as a unitary construction of a homogeneous material. For example, the frame 200, including the first and second end portions 202a and 202b, the first and second side portions 204a and 204b, and the rim 220, can be injection molded of carbon fiber or another material having suitable resistivity/conductivity and static dissipative properties. In other embodiments, other suitable methods and materials can be used to form the frame 200 as a unitary construction of a homogeneous material. In still further embodiments of the present disclosure, a frame can include multiple pieces, possibly of diverse materials, that are assembled to form an integral construction.

The insert panel 300 includes a plurality of pockets 310. Individual pockets 310 are configured to releasably receive a respective microelectronic assembly (not shown in FIG. 1). According to other embodiments of the present disclosure, the pockets 310 can be configured to receive other microelectronic components, e.g., bare chips or wafer portions. The plurality of pockets 310 can be distributed over the insert panel 300 in a plurality of rows and in a plurality of columns. As shown in FIG. 1, individual rows extend parallel to the longitudinal axis A1 and individual columns extend parallel to the lateral axis A2. In other embodiments of the present disclosure, the pockets 310 can have any suitable distribution over the insert panel 300 that is in compliance with JEDEC Design Guide 4.10, for example.

The insert panel 300 can be thermoformed in particular embodiments of the disclosure. As it is used in the present disclosure, the term “thermoform” includes a manufacturing process wherein a thermoplastic sheet or film is heated to its forming temperature before being stretched into or onto a mold and then cooled. Examples of thermoforming in accordance with the present disclosure can include vacuum forming, pressure forming, or a combination thereof. The insert panel 300 can include any suitable thermoplastic material, including tri-laminate polystyrene. According to other embodiments of the present disclosure, the plurality of pockets 310 can be formed by stamping, machining, e.g., stereolithography, or any other suitable process.

The insert panel 300 includes a central region 320 and a peripheral region 340. The central region 320 includes the pockets 310 and the peripheral region 340 overlies the platform 210. The peripheral region 340 can include a plurality of holes 360 through which the retainers 400 extend so as to secure the insert panel 300 to the frame 200.

Continuing to refer to FIG. 1, the retainers 400 are used to releasably secure the insert panel 300 to the frame 200. The retainers 400 can be changed between a coupled arrangement (not shown in FIG. 1) and a decoupled arrangement. In the coupled arrangement, the retainers 400 secure the insert panel 300 to the frame 200 so as to prohibit or at least restrict relative movement between the frame 200 and the insert panel 300. In the decoupled arrangement shown in FIG. 1, the retainers 400 allow the insert plate 300 to be released from the frame 200 so as to permit relative movement, e.g., separation, between the frame 200 and the insert plate 300.

In the embodiment shown in FIG. 1, the retainers 400 can include threaded fasteners, e.g., screws or bolts, which pass through the holes 360 in the peripheral region 340 of the insert panel 300 and threadably engage with threaded receptacles 212 in the frame 200. In other embodiments according to the present disclosure, the retainers 400 can include clips, adhesive, threaded posts, projections carried by the frame 200, or any other suitable releasable fastener. In still other embodiments according to the present disclosure, the insert panel 300 can be retained with respect to the frame 200 without separate fasteners, e.g., via a releasable friction fit between the insert panel 300 and the frame 200. In such a case, the retainer can include mating features, e.g., contact surfaces on the frame 200 and the insert panel 300. In still further embodiments, the frame 200 and the insert panel 300 can be connected via other techniques, e.g., welding.

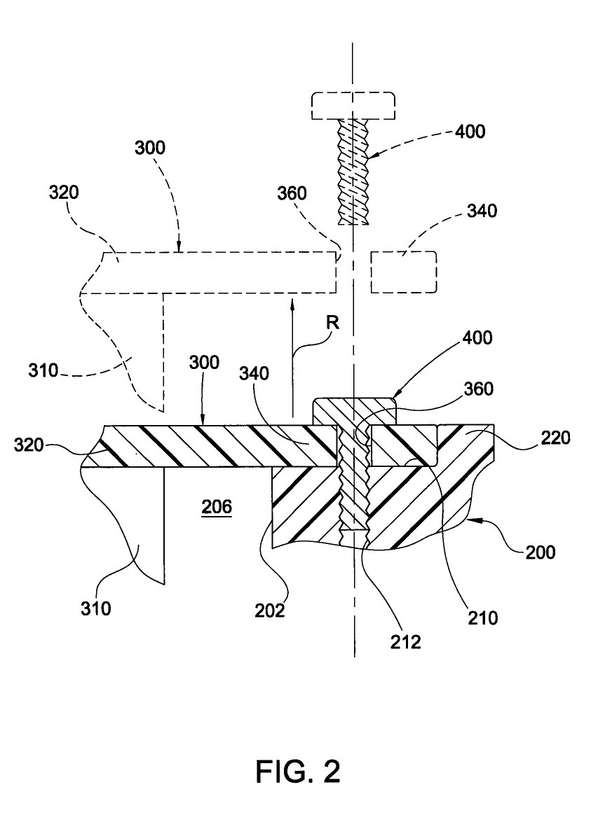

FIG. 2 is a cross-sectional view illustrating a secured configuration (solid lines) and a released configuration (broken lines) of the insert panel 300 with respect to a portion of the frame 200 in accordance with an embodiment of the present disclosure. In the secured configuration, the peripheral region 340 of the insert panel 300 overlies the platform 210 of the frame 200. The rim 220 of the frame 200 positions the insert panel 300 on the platform 210 so that the holes 360 are approximately aligned with the threaded receptacles 212. The insert panel 300 is disposed across the aperture 206 and the pockets 310 project into the aperture 206. In the embodiment shown in FIG. 2, an individual threaded retainer 400 passes through an individual hole 360 in the insert panel 300 and threadably engages an individual threaded receptacle 212. In the released configuration, the individual threaded retainer 400 is withdrawn from the individual threaded receptacle 212 and the insert panel 300 can be separated from the frame 200 in a release direction R.

The insert panel 300, which includes 112 pockets 310 as shown in FIG. 1, can be released from the frame 200 of the handling device 100, and a different insert panel (not shown) can be secured to the frame 200 in its place. The insert plate 300 can be released from the frame 200, for example, when the retainers 400 are in the decoupled arrangement, and a different insert panel can be secured to the frame 200 by repositioning the retainers 400 in the coupled arrangement. Accordingly, the handling device 100 can facilitate using multiple types of insert panels with different numbers, sizes and distributions of pockets, all supported by the same frame 200.

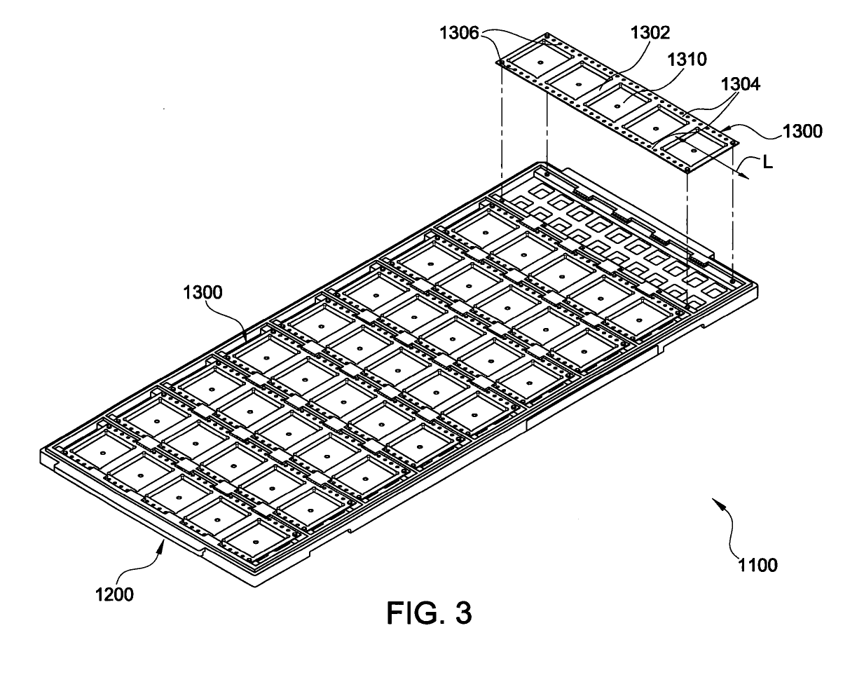

FIG. 3 shows a microelectronic assembly handling device 1100 configured in accordance with another embodiment of the disclosure. In this embodiment, the handling device 1100 includes a frame 1200 that is populated with a different insert than is shown in FIG. 1, e.g., eight insert strips 1300. A ninth insert strip 1300 is shown spaced above the frame 1200 and enlarged for explanatory purposes.

Individual insert strips 1300 include a central region 1302 and two side regions 1304. The central region 1302 includes a plurality of pockets 1310 that can be configured to receive respective microelectronic assemblies. The insert strips 1300 can be lengths of embossed carrier tape, for which the Electronics Industries Alliance (EIA) has promulgated standards. For example, Standard EIA-481-B, “8 mm through 200 mm Embossed Carrier Taping and 8 mm & 12 mm Punched Carrier Taping of Surface Mounted Components for Automatic Handling,” provides dimensions and tolerances necessary to tape surface mount components such that they may be automatically handled. In the embodiment shown in FIG. 3, a single column of five pockets 1310 is disposed along an individual insert strip 1300. In other embodiments, the shape, size, capacity and other characteristics of the insert strips 1300 can be different.

The peripheral regions 1304 extend parallel to a lengthwise direction L1 of the insert strips 1300 and are disposed laterally outside of the pockets 1310 on either side of an individual insert strip 1300. A set of holes 1306 can be disposed in individual peripheral regions 1304.

The insert strips 1300, similar to the insert panel 300 described above, can be thermoformed. Accordingly, the foregoing examples of thermoforming in accordance with the present disclosure (vacuum forming, pressure forming, or a combination thereof) can be used to form the insert strips 1300. The insert strips 1300 can include any suitable thermoplastic material, including tri-laminate polystyrene. According to other embodiments of the present disclosure, the plurality of pockets 1310 can be formed by stamping, machining, e.g., stereolithography, or another suitable process.

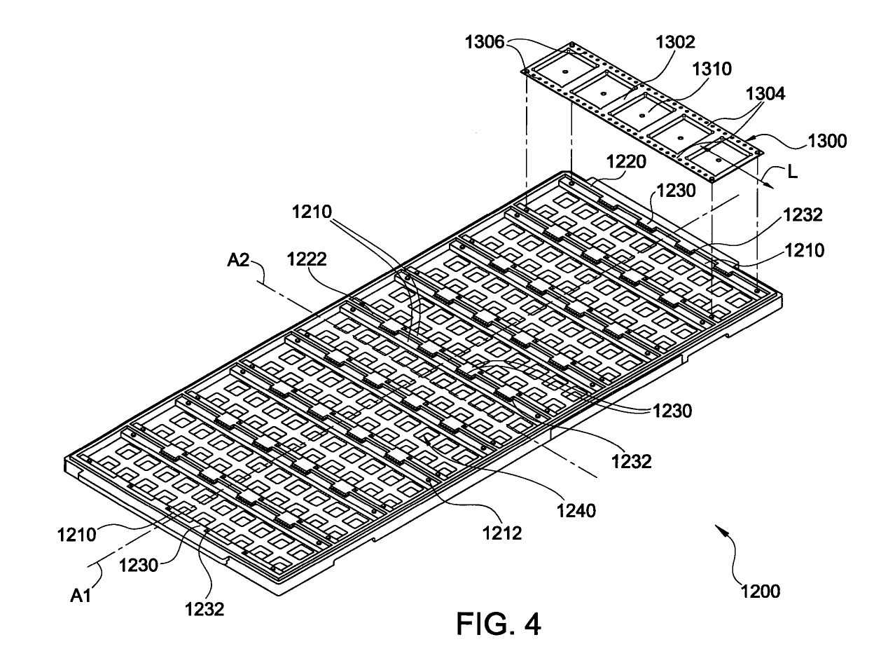

FIG. 4 shows the frame 1200 of the handling device 1100 that is shown in FIG. 3, with the insert strips 1300 removed. According to the embodiment shown in FIG. 4, the frame 1200 has a rectangular shape and size in accordance with JEDEC design requirements. According to other embodiments, the frame can have other suitable shapes and/or sizes. The frame 1200 includes ledges 1210 to support peripheral regions 1304 of the insert strips 1300 and includes a rim 1220 for positioning the insert strips 1300 on the frame 1200.

The ledges 1210 of the frame 1200 can be spaced along a longitudinal axis A1 and extend parallel to a lateral axis A2. In the embodiment shown in FIG. 4, there are 18 ledges 1210 (only four are indicated in FIG. 4 for the sake of clarity) so as to correspond to the number of peripheral regions 1304 for nine insert strips 1300. The outer rectangular shape of the frame 1200 is interiorly partitioned by eight pairs of the ledges 1210, and each of the eight interior pairs of the ledges 1210 is separated by a respective rib 1222 (only one is indicated in FIG. 4 for the sake of clarity). The rim 1220 and the ribs 1222 position individual insert strips 1300 on the frame 1200. The spacing along the longitudinal axis A1 between adjacent ones of the rim 1220 and the ribs 1222 corresponds to a width of individual insert strips 1300, i.e., measured transversely to the lengthwise direction L of the insert strips 1300. According to other embodiments, different numbers of ledges and ribs can be disposed interiorly of a rectangular frame to accommodate different numbers and/or widths of insert strips.

The frame 1210 can also include tabs 1230 that can project parallel to the longitudinal axis A1. The tabs 1230 (only four are indicated in FIG. 4 for the sake of clarity) project from the rim 1220 and the ribs 1222 to define gaps 1232 between the tabs 1230 and respective ledges 1210. The gaps 1232 are configured to receive the peripheral regions 1304 of individual insert strips 1300. In other embodiments according to the present disclosure, any suitable structure other than the tabs 1230 can be used to prevent or at least restrict separation of individual insert strips 1300 from the frame 1200. Posts 1212 can project from the ledges 1210 for registering, e.g., locating, the insert strips 1300 with respect to the frame 1200. In the embodiment shown in FIG. 4, the tabs 1230 can prevent or at least restrict the insert strips 1300 from separating from the frame 1200 and the posts 1212 can prevent or at least restrict the insert strips 1300 from sliding on the frame 1200. In other embodiments of the present disclosure, the insert strips 1300 can be pressed onto several of the posts 1210 such that the insert strips 1300 are retained with respect to the frame 1210 via a friction fit without the tabs 1230.

In the embodiment shown in FIG. 4, the frame 1200 can include a grid 1240 that can underlie the ledges 1210 relative to the tabs 1230. The grid 1240 can contiguously support the bottom surfaces of the pockets 1310 of the insert strips 1300. According to other embodiments, any suitable structure other than the grid 1240 can be used to provide support for pockets.

The frame 1200, similar to the frame 200 described above, can be formed as a unitary construction of a homogeneous material. For example, the frame 1200, including the ledges 1210, the posts 1212, the rim 1220, the ribs 1222, the tabs 1230 and the grid portion 1240 can be injection molded of carbon fiber or another material having suitable resistivity/conductivity and static dissipative properties. In other embodiments, other suitable methods and materials can be used to form the frame 1200 as a unitary construction of a homogeneous material. In still further embodiments of the present disclosure, a frame can include multiple pieces, possibly of diverse materials, that are assembled to form an integral construction.

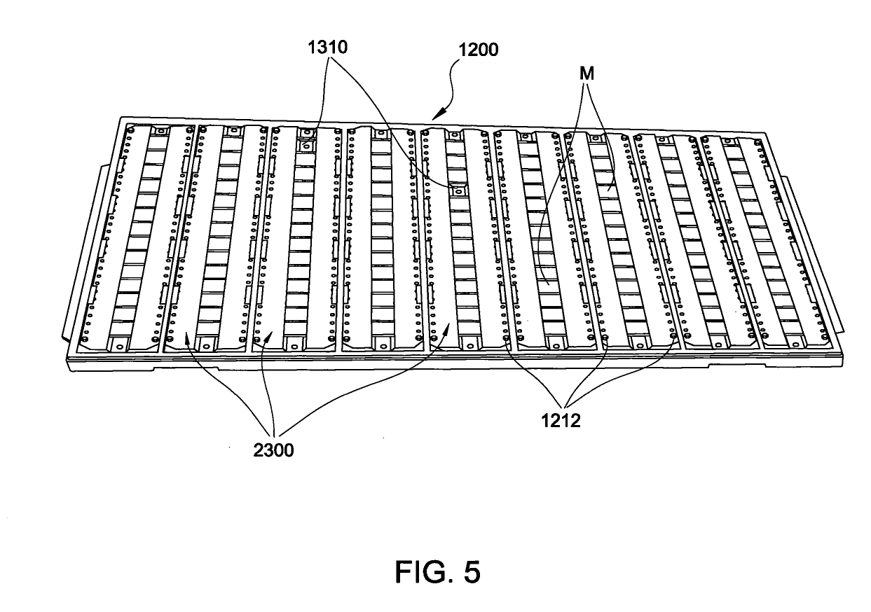

FIG. 5 shows another embodiment according to the present disclosure that includes insert strips 2300 supported by the same frame 1200 and microelectronic assemblies M (only two are indicated in FIG. 5 for the sake of clarity) disposed in individual pockets 1310. In the embodiment shown in FIG. 5, 14-pocket insert strips 2300 have been secured to the frame 1200 in place of the five-pocket insert strips 1300 shown in FIG. 3. In particular, individual insert strips 1300 that include five pockets 1310, as shown in FIG. 3, have been released from the frame 1200, and individual insert strips 2300 that include 14 pockets, as shown in FIG. 5, have been secured to the frame 1200. Accordingly, the number, size, and other characteristics of pockets included in an inset strip can be varied to accommodate various microelectronic assemblies and/or components while the same frame can be used to support the different insert strips.

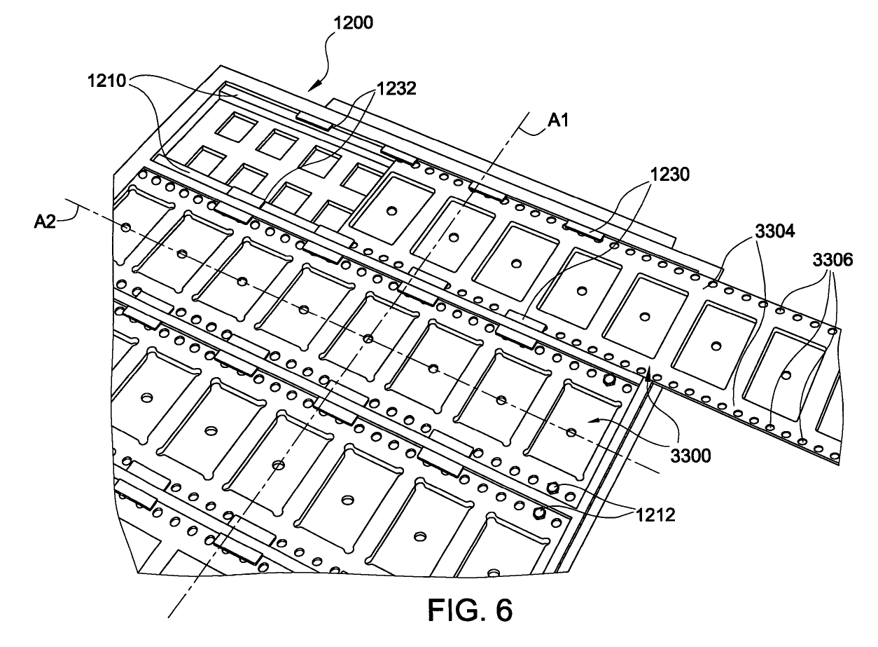

FIG. 6 is an enlarged view of a portion of a handling device similar to that shown in FIG. 3, with eight-pocket (rather than five-pocket) insert strips 3300 installed. With reference to FIG. 6, a method by which insert strips can be secured and released, thereby facilitating changing insert strips while still using the same frame, will now be described. To secure individual insert strips 3300 to the frame 1200, the insert strip 3300 can be displaced in the direction parallel to the lateral axis A2 between the ledges 1210 and the tabs 1230 so as to dispose side regions 3304 of the insert strip 3300 in the gaps 1232. At least one hole 3306 in the insert strip 3300 can then be pressed over a post 1212 to secure the insert strip 3300 on the frame 1200. To release an insert strip 3300 from the frame 1200, the insert strip 3300 is displaced, e.g., lifted, such that the posts 1212 no longer engage holes 3306 in the insert strip 3300 and the insert strip 3300 is displaced in its lengthwise direction so as to extricate side regions of the insert strip from the gaps 1232. According to other embodiments, insert strips with different numbers, sizes, distributions, or other characteristics of pockets can all be installed on the same frame 1200.

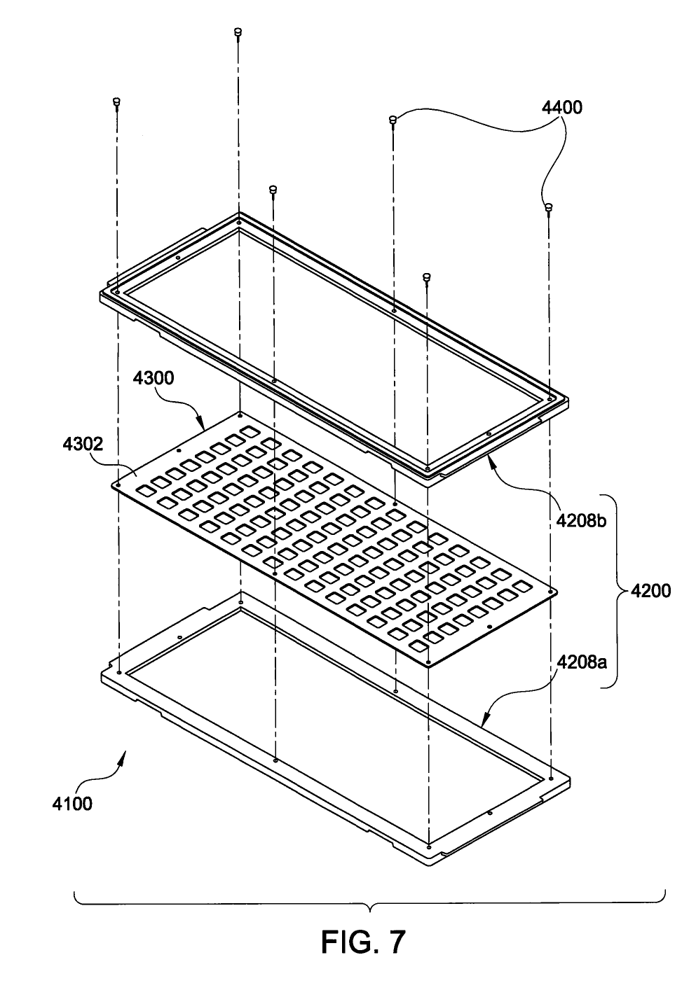

FIG. 7 is an exploded, schematic illustration of a microelectronic assembly handling device 4100 configured in accordance with an embodiment of the disclosure. In this embodiment, the handling device 4100 includes a frame 4200, an insert plate 4300, and one or more retainers 4400. In particular, the insert plate 4300 includes a peripheral region 4302 sandwiched between first and second sections 4208a and 4208b of the frame 4200, and the retainers 4400 releasably secure together the first and second sections 4208a and 4208b of the frame 200 with the insert plate 4300 sandwiched between.

In contrast to conventional microelectronic assembly/component handling devices, embodiments of handling devices in accordance with the present disclosure do not require a tray that is injection molded. Instead, one or more inserts can be thermoformed, e.g., vacuum formed, and secured to an injection molded frame. Thus, according to the present disclosure, standardized injection molded frames can be interchangeably used with a number of various vacuum formed inserts customized to a specific microelectronic assembly or component. In particular embodiments, the custom vacuum formed insert can reduce the start-up cost to create a mold to not more than two thousand dollars and can reduce the time required to build a quantity of trays to not more than four weeks. Accordingly, the time required to develop a tray can be reduced and/or excluded as the limiting factor in developing a new microelectronic assembly.

From the foregoing, it will be appreciated that specific embodiments of the disclosure have been described herein for purposes of illustration, but that various modifications may be made without deviating from the disclosure. For example, structures and/or processes described in the context of particular embodiments may be combined or eliminated in other embodiments. In particular, the attachment features described above with reference to particular embodiments can include one or more additional features or components, or one or more of the features described above can be omitted. In addition, trays according to the present disclosure can also be used to handle a variety of semiconductor components, including packaged dies, bare dies and wafers, e.g., unsingulated wafers or wafer portions and repopulated carrier wafers. In other embodiments according to the present disclosure, the inserts or strips can also be fastened to the bottom-side of the frame, e.g., to provide access for bottom-up handling of the semiconductor components. Moreover, while advantages associated with certain embodiments of the disclosure have been described in the context of these embodiments, other embodiments may also exhibit such advantages, and not all embodiments need necessarily exhibit such advantages to fall within the scope of the disclosure. Accordingly, the disclosure can include other embodiments not shown or described above.

I/We claim:

1. A handling device for microelectronic assemblies, comprising:
a frame including a first end portion, a second end portion spaced along a longitudinal axis from the first end portion, a first side portion coupling the first and second end portions, and a second side portion coupling the first and second end portions and spaced along a lateral axis from the first side portion;
an insert releasably disposed on the frame and including a plurality of pockets, with individual pockets positioned to releasably receive a respective one of the microelectronic assemblies; and
a retainer positioned to secure and release the insert with respect to the frame.

2. The handling device of claim 1, wherein the retainer comprises a projection carried by the frame and wherein the insert includes a hole positioned to releasably receive the projection.

3. The handling device of claim 1, wherein the insert includes a hole and the retainer comprises a fastener extending through the hole and releasably engaging the frame.

4. The handling device of claim 1, wherein the retainer comprises a first surface of the frame in contact with a second surface of the insert.

5. The handling device of claim 1, wherein the frame comprises:
a ledge positioned to support a peripheral region of the insert; and
a tab spaced from the ledge so as to define a gap positioned to receive the peripheral portion of the insert.

6. The handling device of claim 5, wherein the first end portion includes—
a first ledge positioned to support a first peripheral region of the insert; and
a first tab projecting toward the second end portion, the first tab being spaced from the first ledge so as to define a first gap positioned to receive the first peripheral region of the insert; and
wherein the second end portion includes—
a second ledge positioned to support a second peripheral region of the insert; and
a second tab projecting toward the first end portion, the second tab being spaced from the second ledge so as to define a second gap positioned to receive the second peripheral region of the insert.

7. The handling device of claim 1, wherein the first end portion, the second end portion, the first side portion, and the second side portion are formed from a unitary construction of a homogeneous material.

8. The handling device of claim 1, wherein the frame is injection molded.

9. The handling device of claim 1, wherein the insert comprises an insert panel overlying a platform defined by the first and second side portions and by the first and second end portions.

10. The handling device of claim 1, wherein individual pockets releasably receive respective microelectronic assemblies.

11. The handling device of claim 1, wherein the insert comprises a plurality of insert strips extending between the first and second side portions.

12. The handling device of claim 11, wherein individual insert strips comprise a set of the plurality of pockets, and individual pockets releasably receive respective microelectronic assemblies.

13. The handling device of claim 1, wherein the insert is vacuum molded.

14. The handling device of claim 1, wherein the frame comprises a first section and a second section overlying the first section, and the insert is positioned between the first and second sections.

15. A handling device for microelectronic assemblies, comprising:
a frame being injection molded as a unitary construction of a homogeneous material,
the frame including—
a first end portion;
a second end portion spaced along a longitudinal axis from the first end portion;
a first side portion coupling the first and second end portions; and
a second side portion coupling the first and second end portions and spaced along a lateral axis from the first side portion;
wherein the first end portion, the second end portion, the first side portion and the second side portion combine to form a platform, form a rim surrounding the platform, and define an aperture;
an insert panel being vacuum molded and removably disposed across the aperture and inside of the rim, wherein the insert panel includes—
a peripheral region overlying the platform; and
a central region having a plurality of pockets, with individual pockets positioned to releasably receive a respective microelectronic assemblies; and
a retainer positioned to secure and release the insert panel and the frame, the retainer having a coupled configuration with respect to the frame to secure the insert panel to the frame, and the retainer having a decoupled configuration with respect to the frame to release the insert panel from the frame.

16. The handling device of claim 15, wherein the retainer comprises a threaded fastener and the retainer passes through a hole in the insert panel and threadably engages the frame.

17. A handling device for microelectronic assemblies, comprising:
a frame being injection molded as a unitary construction of a homogeneous material,
the frame including—
a first end portion having a first ledge and a first tab spaced from the first ledge to define a first gap;
a second end portion spaced along a longitudinal axis from the first end portion, the second end portion having a second ledge and a second tab spaced from the second ledge to define a second gap;
a first side portion coupling the first and second end portions;
a second side portion coupling the first and second end portions and spaced along a lateral axis from the first side portion;
an interior portion extending between the first and second side portions and disposed along the longitudinal axis between the first and second end portions, the interior portion including—
a pair of interior ledges extending parallel to the lateral axis;
a rib extending parallel to the lateral axis and being longitudinally positioned between the interior ledges; and
interior tabs projecting from the rib and spaced from individual interior ledges to define respective interior gaps;
a first insert strip being vacuum formed and removably disposed between the first end portion and the interior portion, the first insert strip including—
a pair of first peripheral regions extending parallel to the lateral axis, with individual first peripheral regions being received in the first and individual interior gaps, respectively; and
a first central region extending parallel to the lateral axis and being longitudinally positioned between the first peripheral regions, the first central region having a plurality of first pockets, with individual first pockets positioned to releasably receive a respective microelectronic assembly; and
a second insert strip being vacuum formed and removably disposed between the second end portion and the interior portion, the second insert strip including—
a pair of second peripheral regions extending parallel to the lateral axis, with individual second peripheral regions being received in the second and individual interior gaps, respectively; and
a second central region extending parallel to the lateral axis and being longitudinally positioned between the second peripheral regions, the second central region having a plurality of second pockets, with individual second pockets positioned to releasably receive a respective microelectronic assembly.

18. The handling device of claim 17, wherein the frame further comprises:
a first grid portion being coupled to the frame and underlying the plurality of first pockets, and individual first pockets include a bottom contiguously resting on the first grid; and
a second grid portion being coupled to the frame and underlying the plurality of second pockets, and individual second pockets include a bottom contiguously resting on the second grid.

19. The handling device of claim 17, wherein the interior portion comprises first and second interior portions extending between the first and second side portions, the first interior portion being disposed between the first end portion and the second interior portion, and the second interior portion being disposed between the second end portion and the first interior portion.

20. The handing device of claim 19, wherein the first interior portion comprises a pair of first interior ledges, a first rib, and first interior tabs projecting from the first rib and spaced from the individual first interior ledges to define respective first interior gaps; and
wherein the second interior portion comprises a pair of second interior ledges, a second rib, and second interior tabs projecting from the second rib and spaced from the individual second interior ledges to define respective second interior gaps; and
wherein individual first peripheral regions of the first insert strip are received in the first and first interior gaps, respectively; and
wherein individual second peripheral regions of the second insert strip are received in the second and second interior gaps, respectively.

21. The handling device of claim 20, further comprising:
a third insert strip being vacuum formed and removably disposed between the first and second interior portions, the third insert strip including—
a pair of third peripheral regions extending parallel to the lateral axis, with individual third peripheral regions being respectively received in the first interior and second interior gaps; and
a third central region extending parallel to the lateral axis and being longitudinally positioned between the third peripheral regions, the third central region having a plurality of third pockets, with individual third pockets positioned to releasably receive a respective microelectronic assembly; and
a third grid portion being coupled to the frame and underlying the plurality of third pockets, and individual third pockets include a bottom contiguously resting on the third grid.

22. A method of manufacturing a handling device for microelectronic assemblies, comprising:
forming a frame according to a first process;
forming an insert according to a second process, the second process being different from the first process, the second process including forming a plurality of pockets in the insert, with individual pockets being positioned to releasably receive a respective microelectronic assembly; and
securing the insert to the frame.

23. The method of claim 22, wherein the first process comprises injection molding, and the second process comprises thermoforming.

24. The method of claim 23, wherein the second process comprises at least one of vacuum forming and pressure forming.

25. The method of claim 22, wherein the insert comprises an insert panel and wherein securing comprises overlaying the insert panel on the frame and coupling the insert panel to the frame with a fastener.

26. The method of claim 22, wherein the first process comprises forming gaps in the frame, and wherein securing comprises sliding the insert into the gaps.

27. A method of handling microelectronic assemblies, comprising:
releasably securing a first insert to a first frame, the first insert having a plurality of pockets positioned to receive a first number of the microelectronic assemblies having a first size and a first shape;
removing the first insert from the first frame; and
releasably securing a second insert to the first frame, the second insert having a plurality of pockets positioned to receive a second number of the microelectronic assemblies having a second size and a second shape, wherein at least one of the second number, second size, and second shape is different than the first number, first size, and first shape, respectively.

28. The method of claim 27, wherein releasably securing includes coupling with a fastener, and wherein removing includes decoupling the fastener and separating the first insert from the first frame.

29. The method of claim 27, further comprising:
releasably securing the first insert to a second frame.

30. The method of claim 27, further comprising:
populating the first insert with first microelectronic assemblies having the first size and shape while the first insert is carried by the first frame; and
populating the second insert with second microelectronic assemblies having the second size and shape while the second insert is carried by the first frame.
